(19) United States
(12) Patent Application Publication
(10) Pub. No.: US 2024/0244976 A1
(43) Pub. Date: Jul. 18, 2024

(54) THERMOELECTRIC CONVERSION UNIT, METHOD OF MANUFACTURING THERMOELECTRIC CONVERSION UNIT, AND METHOD OF USING THERMOELECTRIC CONVERSION UNIT

(71) Applicant: Panasonic Intellectual Property Management Co., Ltd., Osaka (JP)

(72) Inventor: HIROMASA TAMAKI, Osaka (JP)

(21) Appl. No.: 18/585,024

(22) Filed: Feb. 22, 2024

Related U.S. Application Data
(63) Continuation of application No. PCT/JP2022/030058, filed on Aug. 5, 2022.

(30) Foreign Application Priority Data
Sep. 10, 2021 (JP) 2021-147445

(51) Int. Cl. H10N 10/17; H10N 10/01

(52) U.S. Cl. CPC H10N 10/17; H10N 10/01

(57) ABSTRACT

A thermoelectric conversion unit includes: a first fluid passage that has a first main surface and a second main surface and through which a first fluid flows; a second fluid passage through which a second fluid having a higher temperature than the first fluid flows; a pair of thermoelectric modules including a first thermoelectric module and a second thermoelectric module; and a pair of magnetic body portions disposed inside of or on a surface of the first fluid passage along a predetermined direction from the first main surface toward the second main surface. Each of the first and second thermoelectric modules generates an electromotive force based on a temperature difference between the first fluid and the second fluid. Magnetic bodies of the pair of magnetic body portions are disposed so that the same magnetic poles thereof face each other, and generate magnetic forces that repel each other.

### BACKGROUND

### 1. Technical Field

The present disclosure relates to a thermoelectric conversion unit that generates an electromotive force based on a temperature difference, a method of manufacturing the thermoelectric conversion unit, and a method of using the thermoelectric conversion unit.

### 2. Description of the Related Art

Existing thermoelectric conversion units (see, for example, Japanese Unexamined Patent Application Publication No. 10-213360 and Japanese Unexamined Patent Application Publication No. 2006-86210) include a low-temperature fluid passage through which a low-temperature fluid flows, a high-temperature fluid passage through which a high-temperature fluid flows, and a thermoelectric module disposed between the low-temperature fluid passage and the high-temperature fluid passage. By using the Seebeck effect, the thermoelectric module generates an electromotive force based on a temperature difference between the high-temperature fluid that flows through the high-temperature fluid passage and the low-temperature fluid that flows through the low-temperature fluid passage.

In the existing thermoelectric conversion units described above, a magnet is disposed in each of the low-temperature fluid passage and the high-temperature fluid passage. Magnetic forces that attract each other are generated between the magnet disposed in the low-temperature fluid passage (hereafter, referred to as “first magnet”) and the magnet disposed in the high-temperature fluid passage (hereafter, referred to as “second magnet”), and thus the low-temperature fluid passage and the high-temperature fluid passage are fixed to each other.

### SUMMARY

However, in the thermoelectric conversion units described above, the heat of the high-temperature fluid that flows through the high-temperature fluid passage is dissipated through the second magnet, and thus a problem arises in that the efficiency of heat transfer from the high-temperature fluid to the thermoelectric module decreases.

The temperature of the second magnet increases because the heat of the high-temperature fluid that flows through the high-temperature fluid passage is transferred to the second magnet. Thus, the magnetic moment of the second magnet decreases, and the thermal contact between the low-temperature fluid passage and the thermoelectric module and the thermal contact between the high-temperature fluid passage and the thermoelectric module become insufficient. As a result, a problem arises in that the power generation efficiency of the thermoelectric module decreases.

One non-limiting and exemplary embodiment provides a thermoelectric conversion unit that can increase power generation efficiency, a method of manufacturing the thermoelectric conversion unit, and a method of using the thermoelectric conversion unit.

In one general aspect, the techniques disclosed here feature a thermoelectric conversion unit including: a first fluid passage that has a first main surface and a second main surface opposite to the first main surface and through which a first fluid flows between the first main surface and the second main surface; a second fluid passage that is disposed so as to face the first main surface and the second main surface and through which a second fluid having a temperature higher than a temperature of the first fluid flows; a pair of thermoelectric modules that include a first thermoelectric module disposed between the second fluid passage and the first main surface and a second thermoelectric module disposed between the second fluid passage and the second main surface; and a pair of magnetic body portions that are disposed inside of or on a surface of the first fluid passage along a predetermined direction from the first main surface toward the second main surface. Each of the first thermoelectric module and the second thermoelectric module generates an electromotive force based on a temperature difference between the temperature of the first fluid and the temperature of the second fluid. Each of the pair of magnetic body portions includes a magnetic body. The magnetic bodies of the pair of magnetic body portions are disposed so that magnetic poles thereof that are the same as each other face each other, and the magnetic bodies generate magnetic forces that repel each other.

With the thermoelectric conversion unit according to an aspect of the present disclosure and the like, it is possible to increase power generation efficiency.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a perspective view of a thermoelectric conversion unit according to a first embodiment;

FIG. 2 is a sectional view of the thermoelectric conversion unit according to the first embodiment taken along line II-II of FIG. 1;

FIG. 3 is a partial sectional view of the thermoelectric conversion unit according to the first embodiment taken along line III-III of FIG. 2;

FIG. 4 illustrates the configuration of a thermoelectric generator according to the first embodiment;

FIG. 5 is a plan view of the thermoelectric generator according to the first embodiment;

FIG. 6 is a partial sectional view of a thermoelectric conversion unit according to a modification of the first embodiment;

FIG. 7 is a partial sectional view of a thermoelectric conversion unit according to a second embodiment;

FIG. 8 is a partial sectional view of a thermoelectric conversion unit according to a first modification of the second embodiment;

FIG. 9 is a partial sectional view of a thermoelectric conversion unit according to a second modification of the second embodiment;

FIG. 10 is a partial sectional view of a thermoelectric conversion unit according to a third embodiment;

FIG. 11 is a flowchart of a method of manufacturing the thermoelectric conversion unit according to the third embodiment;

FIG. 12 is a view for illustrating the method of manufacturing the thermoelectric conversion unit according to the third embodiment;

FIG. 13 is a partial sectional view of a thermoelectric conversion unit according to a modification of the third embodiment;

FIG. 14 is a perspective view of a thermoelectric conversion unit according to a fourth embodiment;

FIG. 15A is a sectional view of the thermoelectric conversion unit according to the fourth embodiment in a first switched state taken along line XVA-XVA of FIG. 14;

FIG. 15B is a sectional view of the thermoelectric conversion unit according to the fourth embodiment in a second switched state taken along line XVB-XVB of FIG. 14;

FIG. 15C is a sectional view of the thermoelectric conversion unit according to the fourth embodiment in a third switched state taken along line XVC-XVC of FIG. 14;

FIG. 16 is a partial sectional view of the thermoelectric conversion unit according to the fourth embodiment taken along line XVI-XVI of FIG. 15A; and

FIG. 17 is a sectional view of the thermoelectric conversion unit according to the first embodiment taken along line XVII-XVII of FIG. 1.

### DETAILED DESCRIPTIONS

A thermoelectric conversion unit according to an aspect of the present disclosure includes: a first fluid passage that has a first main surface and a second main surface opposite to the first main surface and through which a first fluid flows between the first main surface and the second main surface; a second fluid passage that is disposed so as to face the first main surface and the second main surface and through which a second fluid having a temperature higher than a temperature of the first fluid flows; a pair of thermoelectric modules that include a first thermoelectric module disposed between the second fluid passage and the first main surface and a second thermoelectric module disposed between the second fluid passage and the second main surface; and a pair of magnetic body portions that are disposed inside of or on a surface of the first fluid passage along a predetermined direction from the first main surface toward the second main surface. Each of the first thermoelectric module and the second thermoelectric module generates an electromotive force based on a temperature difference between the temperature of the first fluid and the temperature of the second fluid. Each of the pair of magnetic body portions includes a magnetic body. The magnetic bodies of the pair of magnetic body portions are disposed so that magnetic poles thereof that are the same as each other face each other, and the magnetic bodies generate magnetic forces that repel each other.

With the present aspect, the pair of magnetic body portions are disposed in or on the first fluid passage. Thus, the magnetic bodies of the magnetic body portions are cooled by the first fluid that has a comparatively low temperature and that flows through the first fluid passage, and therefore it is possible to suppress increase in the temperature of the magnetic bodies. As a result, it is possible to suppress decrease of the magnetic moment of the magnetic bodies, the thermal contact between the first fluid passage and the thermoelectric modules is promoted, and it is possible to increase the power generation efficiency of the pair of thermoelectric modules. The first fluid passage, the second fluid passage, and the pair of thermoelectric modules are fixed to each other by using the magnetic forces with which the magnetic bodies of the pair of magnetic body portions repel each other. Thus, the relative positional relationship among the first fluid passage, the second fluid passage, and the pair of thermoelectric modules has a degree of freedom. As a result, for example, even when a vibration, a thermal impact, or the like is applied to the thermoelectric conversion unit from the outside, it is possible to absorb a stress applied to the pair of thermoelectric modules and it is possible to suppress damage to the pair of thermoelectric modules, because the first fluid passage, the second fluid passage, and the pair of thermoelectric modules become displaced relative to each other.

Two or more sets may be disposed in the predetermined direction, each of the sets including the first fluid passage, the pair of magnetic body portions, and the pair of thermoelectric modules.

With the present aspect, it is possible to make thermoelectric conversion unit compact.

The thermoelectric conversion unit may further include a guide member, and the guide member may extend through an inside of the first fluid passage in the predetermined direction and restrain the first fluid passage from becoming displaced with respect to the pair of thermoelectric modules in a direction crossing the predetermined direction.

With the present aspect, when the magnetic bodies of the pair of magnetic body portions repel each other, it is possible to maintain the relative positional relationship between the first fluid passage and the pair of thermoelectric modules in the direction crossing the predetermined direction.

Both end portions of the guide member in a longitudinal direction may include a first end portion and a second end portion, and the first end portion and the second end portion may be respectively fixed to the pair of thermoelectric modules or the second fluid passage.

With the present aspect, it is possible to fix the guide member stably.

The first end portion, the second end portion, or each of the first end portion and the second end portion may include an adjuster; and when the adjuster is controlled, the guide member may be switched between a first state in which the guide member is fixed to the pair of thermoelectric modules or the second fluid passage and a second state in which the guide member is released from being fixed to the pair of thermoelectric modules or the second fluid passage.

With the present aspect, it is possible to assemble the thermoelectric conversion unit easily by controlling the adjuster.

The first fluid passage may include a pair of grooves that respectively protrude toward the pair of thermoelectric modules, and the pair of magnetic body portions may be respectively disposed inside of the pair of grooves.

With the present aspect, it is possible to dispose the magnetic body portions in the grooves compactly.

The first fluid passage may include a pair of first fluid passages, the pair of first fluid passages may be disposed so as to face each other in the predetermined direction, and the pair of magnetic body portions may be disposed between the pair of first fluid passages.

With the present aspect, the magnetic bodies of the pair of magnetic body portions repel each other, and thus it is possible to easily press the pair of first fluid passages respectively against the pair of thermoelectric modules.

The second fluid passage may include a pin-shaped heat-transfer fin disposed along the predetermined direction, plate-shaped heat-transfer fins disposed along the predetermined direction so as to face each other, or the pin-shaped heat-transfer fin and the plate-shaped heat-transfer fins.

With the present aspect, it is possible to efficiently transfer heat of the second fluid that flows through second fluid passage to the thermoelectric modules via the pin-shaped heat-transfer fin and/or the plate-shaped heat-transfer fins.

Each of the pair of thermoelectric modules may have a third main surface that faces the first fluid passage and a fourth main surface that faces the second fluid passage, and, when PoS is defined as a pressure that the third main surface of each of the pair of thermoelectric modules receives from the first fluid passage, the PoS may satisfy 10 kPa≤PoS≤1 MPa.

With the present aspect, it is possible to effectively promote thermal contact between the first fluid passage and the thermoelectric module.

Each of the pair of thermoelectric modules may have a third main surface that faces the first fluid passage and a fourth main surface that faces the second fluid passage, and a heat-transfer member may be interposed in a first gap between the first fluid passage and the third main surface, in a second gap between the second fluid passage and the fourth main surface, or between the first gap and the second gap.

With the present aspect, it is possible to increase the efficiency of heat transfer from the first fluid passage to the thermoelectric modules and/or the efficiency of heat transfer from the second fluid passage to the thermoelectric modules.

The heat-transfer member may be a thermally conductive sheet, thermally conductive grease, or the thermally conductive sheet and the thermally conductive grease.

With the present aspect, it is possible to easily interpose the heat-transfer member in the gap between the first fluid passage and the third main surface of the thermoelectric module and/or the gap between the second fluid passage and the fourth main surface of the thermoelectric module.

The magnetic body may be a permanent magnet.

With the present aspect, it is possible to increase a magnetic force with which the magnetic bodies of the pair of magnetic body portions attract each other.

The permanent magnet may be at least one of a samarium-cobalt magnet, a neodymium magnet, an alnico magnet, or a ferrite magnet.

With the present aspect, it is possible to further increase the magnetic force with which the magnetic bodies of the pair of magnetic body portions attract each other.

An outer peripheral surface of the first fluid passage that surrounds a space between the first main surface and the second main surface may be made of stainless steel or a resin.

With the present aspect, it is possible to make the hardness of the outer peripheral surface of the first fluid passage less than the hardness of the first main surface and the second main surface. Thus, when the magnetic bodies of the pair of magnetic body portions repel each other, it is possible for the outer peripheral surface of first fluid passage to absorb a stress that is generated by deformation of the first fluid passage.

A passage switcher for switching flow of the second fluid in the second fluid passage may be disposed the second fluid passage.

With the present aspect, it is possible to easily switch the flow of the second fluid in the second fluid passage.

A method of manufacturing a thermoelectric conversion unit according to an aspect of the present disclosure includes: (a) forming a second fluid passage through which a second fluid having a temperature higher than a temperature of a first fluid flows; (b) placing a first fluid passage that has a first main surface and a second main surface opposite to the first main surface and through which the first fluid flows so that the second fluid passage faces the first main surface and the second main surface; (c) placing a pair of thermoelectric modules that include a first thermoelectric module and a second thermoelectric module, the placing of the pair of thermoelectric modules including placing the first thermoelectric module between the second fluid passage and the first main surface, and placing the second thermoelectric module between the second fluid passage and the second main surface; and (d) placing a pair of magnetic body portions inside of or on a surface of the first fluid passage along a predetermined direction from the first main surface toward the second main surface. An electromotive force is generated by applying a temperature difference between the temperature of the first fluid and the temperature of the second fluid to each of the pair of thermoelectric modules. Each of the pair of magnetic body portions includes a magnetic body. The magnetic bodies of the pair of magnetic body portions are disposed so that magnetic poles thereof that are the same as each other face each other, and the magnetic bodies generate magnetic forces that repel each other.

With the present aspect, the pair of magnetic body portions are disposed in or on the first fluid passage. Thus, the magnetic bodies of the magnetic body portions are cooled by the first fluid that has a comparatively low temperature and that flows through the first fluid passage, and therefore it is possible to suppress increase in the temperature of the magnetic bodies. As a result, it is possible to suppress decrease of the magnetic moment of the magnetic bodies, the thermal contact between the first fluid passage and the thermoelectric modules is promoted, and it is possible to increase the power generation efficiency of the pair of thermoelectric modules. By using the magnetic forces with which the magnetic bodies of the pair of magnetic body portions repel each other, the first fluid passage, the second fluid passage, and the pair of thermoelectric modules are fixed to each other. Thus, the relative positional relationship among the first fluid passage, the second fluid passage, and the pair of thermoelectric modules has a degree of freedom. As a result, for example, even when a vibration, a thermal impact, or the like is applied to the thermoelectric conversion unit from the outside, the first fluid passage, the second fluid passage, and the pair of thermoelectric modules become displaced relative to each other, and thus it is possible to absorb a stress applied to the pair of thermoelectric modules and it is possible to suppress damage to the pair of thermoelectric modules.

The (d) may further include (d1) controlling a repulsive force generated between the magnetic bodies of the pair of magnetic body portions.

With the present aspect, by controlling the repulsive force generated between the magnetic bodies of the pair of magnetic body portions, it is possible to easily control the thermal contact between the first fluid passage and the thermoelectric modules.

The (d) may further include (d2) placing a guide member that extends through at least an inside of the first fluid passage in the predetermined direction, and, in the (d1), both end portions of the guide member in a longitudinal direction may be respectively fixed to the pair of thermoelectric modules or the second fluid passage.

With the present aspect, when the magnetic bodies of the pair of magnetic body portions repel each other, it is possible to maintain the relative positional relationship between the first fluid passage and the pair of thermoelectric modules in the direction crossing the predetermined direction.

In the (d1), the guide member may be switched between a first state in which the guide member is fixed to the pair of thermoelectric modules or the second fluid passage and a second state in which the guide member is released from being fixed to the pair of thermoelectric modules or the second fluid passage.

With the present aspect, by appropriately switching the guide member between the first state and the second state, it is possible to easily control the thermal contact between the first fluid passage and the thermoelectric modules.

The (d) may further include (d3) placing, between the pair of magnetic body portions, a shield member that blocks a magnetic field generated between the pair of magnetic body portions, (d4) placing the pair of magnetic body portions and the shield member between the pair of thermoelectric modules, and (d5) removing the shield member from between the pair of magnetic body portions.

With the present aspect, by placing the shield member between the pair of magnetic body portions, it is possible to easily control a repulsive force generated between the magnetic bodies of the pair of magnetic body portions.

A method of using a thermoelectric conversion unit according to an aspect of the present disclosure is a method a thermoelectric conversion unit including: a first fluid passage that has a first main surface and a second main surface opposite to the first main surface and through which a first fluid flows between the first main surface and the second main surface, a second fluid passage that is disposed so as to face the first main surface and the second main surface and through which a second fluid having a temperature higher than a temperature of the first fluid flows, a pair of thermoelectric modules that include a first thermoelectric module disposed between the second fluid passage and the first main surface and a second thermoelectric module disposed between the second fluid passage and the second main surface, and a pair of magnetic body portions that are disposed inside of or on a surface of the first fluid passage along a predetermined direction from the first main surface toward the second main surface. Each of the pair of magnetic body portions includes a magnetic body. The magnetic bodies of the pair of magnetic body portions are disposed so that magnetic poles thereof that are the same as each other face each other, and the magnetic bodies generate magnetic forces that repel each other. The method includes: transferring heat of the second fluid to each of the pair of thermoelectric modules; and generating an electromotive force by applying a temperature difference between the temperature of the first fluid and the temperature of the second fluid to each of the pair of thermoelectric modules.

With the present aspect, the pair of magnetic body portions are disposed in or on the first fluid passage. Thus, the magnetic bodies of the magnetic body portions are cooled by the first fluid that has a comparatively low temperature and that flows through the first fluid passage, and therefore it is possible to suppress increase in the temperature of the magnetic bodies. As a result, it is possible to suppress decrease of the magnetic moment of the magnetic bodies, the thermal contact between the first fluid passage and the thermoelectric modules is promoted, and it is possible to increase the power generation efficiency of the pair of thermoelectric modules. By using the magnetic forces with which the magnetic bodies of the pair of magnetic body portions repel each other, the first fluid passage, the second fluid passage, and the pair of thermoelectric modules are fixed to each other. Thus, the relative positional relationship among the first fluid passage, the second fluid passage, and the pair of thermoelectric modules has a degree of freedom. As a result, for example, even when a vibration, a thermal impact, or the like is applied to the thermoelectric conversion unit from the outside, the first fluid passage, the second fluid passage, and the pair of thermoelectric modules become displaced relative to each other, and thus it is possible to absorb a stress applied to the pair of thermoelectric modules and it is possible to suppress damage to the pair of thermoelectric modules.

These general or specific aspects may be implemented as a device or a method, or may be implemented as any combination of devices and methods.

Hereafter, embodiments will be described with reference to the drawings.

The embodiments described below each illustrate a general or specific example. Numerical values, shapes, elements, the dispositions of the elements, the connections between the elements, steps, and the order of the steps described in the following embodiments are examples, and are not intended to limit the claims. Elements in the following embodiments that are not described in the independent claims, which show the broadest concepts, are described as optional elements. Each of the figures is not necessarily drawn strictly. In the figures, substantially the same elements are denoted by the same numerals, and redundant descriptions of such elements will be omitted or simplified.

### First Embodiment

### 1-1. Overall Configuration of Thermoelectric Conversion Unit

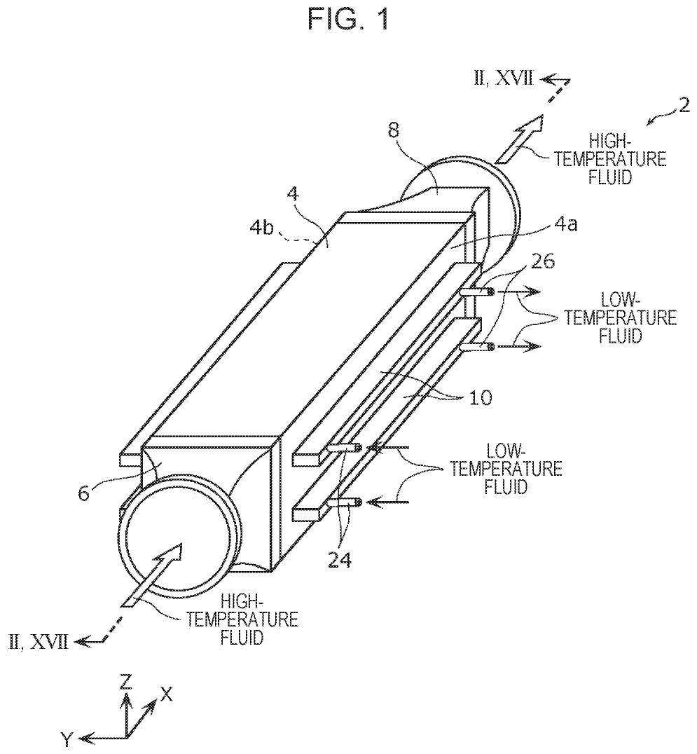

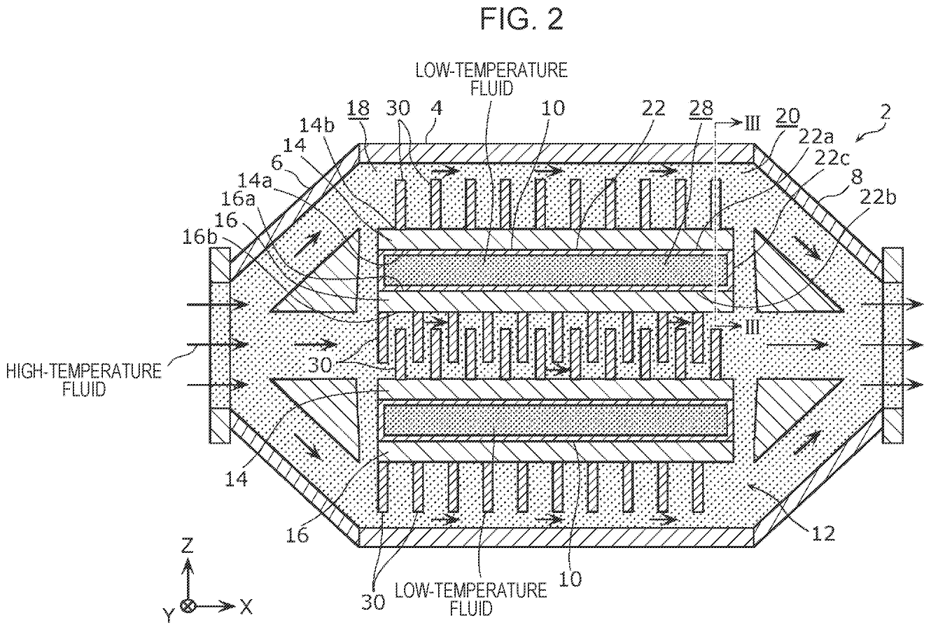

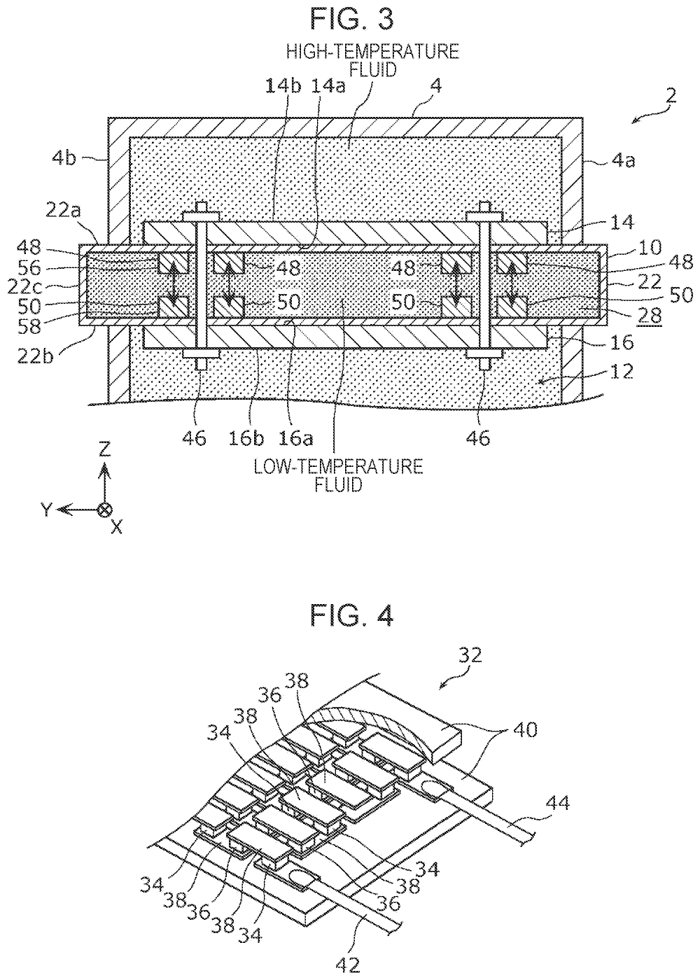

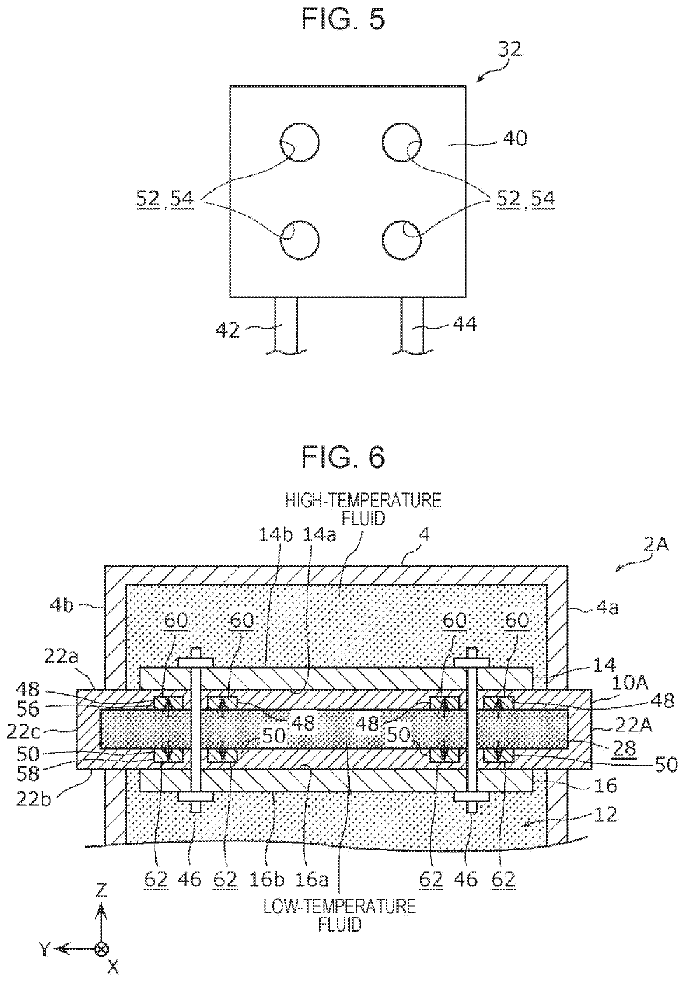

First, referring to FIGS. 1 to 4, the overall configuration of a thermoelectric conversion unit 2 according to a first embodiment will be described. FIG. 1 is a perspective view of the thermoelectric conversion unit 2 according to the first embodiment. FIG. 2 is a sectional view of the thermoelectric conversion unit 2 according to the first embodiment taken along line II-II of FIG. 1. FIG. 3 is a partial sectional view of the thermoelectric conversion unit 2 according to the first embodiment taken along line III-III of FIG. 2. FIG. 4 illustrates the configuration of a thermoelectric generator 32 according to the first embodiment.

In FIGS. 1 to 3, the front-back direction of the thermoelectric conversion unit 2 is the X-axis direction, the left-right direction of the thermoelectric conversion unit 2 is the Y-axis direction, and the up-down direction of the thermoelectric conversion unit 2 is the Z-axis direction.

The thermoelectric conversion unit 2 is a thermoelectric conversion unit that is used to generate electric power by using thermal energy of, for example, exhaust gas discharged from an engine of a vehicle.

As illustrated in FIGS. 1 to 3, the thermoelectric conversion unit 2 includes a body 4, a high-temperature fluid inlet 6 (an example of a second fluid passage), a high-temperature fluid outlet 8 (an example of a second fluid passage), a low-temperature fluid passage 10 (an example of a first fluid passage), a high-temperature fluid passage 12 (an example of a second fluid passage), and a pair of thermoelectric modules 14 and 16 (hereafter, may be referred to as an upper thermoelectric module 14 and a lower thermoelectric module 16).

The body 4 has a tubular shape having a rectangular cross section and extending in the front-back direction (the X-axis direction). A pair of openings 18 and 20 are formed at both end portions of the body 4 in the longitudinal direction.

The high-temperature fluid inlet 6 and the high-temperature fluid outlet 8 are respectively disposed at the pair of openings 18 and 20 of the body 4. The high-temperature fluid inlet 6 and the high-temperature fluid outlet 8 each have a pipe-like shape and communicate with the inside of the body 4.

The low-temperature fluid passage 10 includes a housing 22 having a flat and hollow rectangular-parallelepiped shape and a low-temperature fluid inlet 24 and a low-temperature fluid outlet 26 each having pipe-like shape and protruding outward from a side surface of the housing 22. The housing 22 is made of, for example, stainless steel or the like. The housing 22 has a first main surface 22a and a second main surface 22b opposite to the first main surface 22a. The first main surface 22a faces in the positive direction of the Z axis, and the second main surface 22b faces in the negative direction of the Z axis. As illustrated in FIGS. 1 and 3, most of the housing 22 is disposed inside of the body 4. Both end portions of the housing 22 in the left-right direction (the Y-axis direction) respectively extend through a pair of side surfaces 4a and 4b of the body 4 facing each other and protrude to the outside of the body 4.

An outer peripheral surface 22c of the housing 22 that surrounds the space between the first main surface 22a and the second main surface 22b may be made of a resin. Alternatively, the outer peripheral surface 22c of the housing 22 may be made of stainless steel and have a thickness less than the thickness of each of the first main surface 22a and the second main surface 22b. Thus, it is possible to make the hardness of the outer peripheral surface 22c of the housing 22 less than the hardness of the first main surface 22a and the second main surface 22b.

A low-temperature fluid channel 28, through which a low-temperature fluid (an example of a first fluid) flows, is formed inside of the housing 22. The low-temperature fluid is, for example, cold water, cold air, or the like having a temperature lower than that of a high-temperature fluid (described below). The low-temperature fluid inlet 24 and the low-temperature fluid outlet 26 are disposed with a distance therebetween in the front-back direction (the X-axis direction) and communicate with the low-temperature fluid channel 28 of the housing 22. The low-temperature fluid flows into the low-temperature fluid channel 28 of the housing 22 through the low-temperature fluid inlet 24, flows through the low-temperature fluid channel 28, and then is discharged to the outside through the low-temperature fluid outlet 26.

The high-temperature fluid passage 12 is formed inside of the body 4, and is disposed to face the first main surface 22a, the second main surface 22b, and the outer peripheral surface 22c of the housing 22 of the low-temperature fluid passage 10. The high-temperature fluid passage 12 functions as a high-temperature fluid passage through which a high-temperature fluid (an example of a second fluid) flows. The high-temperature fluid is a fluid having a temperature higher than that of the low-temperature fluid, and is, for example, exhaust gas discharged from an engine of a vehicle or the like.

Pin-shaped (round-bar-shaped) heat-transfer fins 30 are disposed in the high-temperature fluid passage 12. The heat-transfer fins 30 are disposed along a direction from the first main surface 22a toward the second main surface 22b of the housing 22 of the low-temperature fluid passage 10 (the Z-axis direction) (hereafter, also referred to as “a predetermined direction”). The inside and the surface of each heat-transfer fin 30 are made of materials that differ from each other. The heat-transfer fins 30 are respectively fixed to a fourth main surface 14b of the upper thermoelectric module 14 and a fourth main surface 16b of the lower thermoelectric module 16. The inside of each heat-transfer fin 30 is made of a material having high thermal conductivity, such as copper, a copper alloy, aluminum, an aluminum alloy, stainless steel, ceramic, or the like. The surface of the heat-transfer fin 30 is coated with a metal having high corrosion resistance, such as nickel, a nickel alloy, chrome, a chrome alloy, or the like. To coat the surface of the heat-transfer fin 30, it is possible to use a method such as electro-plating, electroless plating, thermal spraying, or the like. For convenience of description, illustration of the heat-transfer fins 30 is omitted in FIG. 3.

The high-temperature fluid flows to the inside of the body 4 through the high-temperature fluid inlet 6, flows through the high-temperature fluid passage 12, which is formed inside of the body 4, in the front-back direction (from the negative side toward the positive side of the X axis), and then is discharged to the outside through the high-temperature fluid outlet 8.

In the present embodiment, the pin-shaped heat-transfer fins 30 are disposed in the high-temperature fluid passage 12. However, this is not a limitation. Plate-shaped (corrugated-plate-shaped or flat-plate-shaped) heat-transfer fins that are disposed along the predetermined direction so as to face each other may be disposed in the high-temperature fluid passage 12. The pin-shaped heat-transfer fins 30 may be disposed along the predetermined direction in the high-temperature fluid passage 12, and/or plate-shaped heat-transfer fins that face each other may be disposed along the predetermined direction in the high-temperature fluid passage 12.

The pair of thermoelectric modules 14 and 16 are disposed so as to face each other with a distance therebetween in the up-down direction. The upper thermoelectric module 14 is disposed between the high-temperature fluid passage 12 and the first main surface 22a of the housing 22 of the low-temperature fluid passage 10. The lower thermoelectric module 16 is disposed between the high-temperature fluid passage 12 and the second main surface 22b of the housing 22 of the low-temperature fluid passage 10.

The upper thermoelectric module 14 has a rectangular flat-plate-like shape, and is interposed, in the up-down direction, between the high-temperature fluid passage 12 and the first main surface 22a of the housing 22 of the low-temperature fluid passage 10. The upper thermoelectric module 14 has a third main surface 14a, which is in contact with (faces) the first main surface 22a of the housing 22 of the low-temperature fluid passage 10, and the fourth main surface 14b, which is in contact with (faces) the high-temperature fluid passage 12. That is, the upper thermoelectric module 14 includes thermoelectric generators that generate an electromotive force due to the Seebeck effect based on a temperature difference between the high-temperature fluid that flows through the high-temperature fluid passage 12 and the low-temperature fluid that flows through the low-temperature fluid passage 10.

A heat-transfer member (not shown) may be interposed in a gap (first gap) between the third main surface 14a of the upper thermoelectric module 14 and the low-temperature fluid passage 10 and/or in a gap (second gap) between the fourth main surface 14b of the upper thermoelectric module 14 and the high-temperature fluid passage 12. The heat-transfer member is, for example, a thermally conductive sheet, thermally conductive grease, or the like. Thus, it is possible to increase the efficiency of heat transfer from the low-temperature fluid passage 10 to the upper thermoelectric module 14 and/or the efficiency of heat transfer from the high-temperature fluid passage 12 to the upper thermoelectric module 14.

The lower thermoelectric module 16 has a rectangular flat-plate-like shape, and is interposed, in the up-down direction, between the high-temperature fluid passage 12 and the second main surface 22b of the housing 22 of the low-temperature fluid passage 10. The lower thermoelectric module 16 has a third main surface 16a, which is in contact with (faces) the second main surface 22b of the housing 22 of the low-temperature fluid passage 10, and the fourth main surface 16b, which is in contact with (faces) the high-temperature fluid passage 12. That is, the lower thermoelectric module 16 includes thermoelectric generators that generate an electromotive force due to the Seebeck effect based on a temperature difference between the high-temperature fluid that flows through the high-temperature fluid passage 12 and the low-temperature fluid that flows through the low-temperature fluid passage 10.

A heat-transfer member (not shown) may be interposed in a gap between the third main surface 16a of the lower thermoelectric module 16 and the low-temperature fluid passage 10 and/or in a gap between the fourth main surface 16b of the lower thermoelectric module 16 and the high-temperature fluid passage 12. The heat-transfer member is, for example, a thermally conductive sheet, thermally conductive grease, or the like. Thus, it is possible to increase the efficiency of heat transfer from the low-temperature fluid passage 10 to the lower thermoelectric module 16 and/or the efficiency of heat transfer from the high-temperature fluid passage 12 to the lower thermoelectric module 16.

Here, the thermoelectric generators described above each have, for example, a π-type structure. As illustrated in FIG. 4, in the thermoelectric generator 32 having a π-type structure, P-type elements 34 and N-type elements 36 are electrically connected in series via electrodes 38 and are disposed so that heat flows in parallel. The P-type elements 34 and the N-type elements 36 are covered by a pair of rectangular ceramic plates 40 from both sides. A first end of each P-type element 34 and a first end of each N-type element 36 are disposed on the high-temperature side, and a second end of each P-type element 34 and a second end of each N-type element 36 are disposed on the low-temperature side. Thus, a temperature difference is generated between the first end and the second end of each P-type element 34, and a temperature difference is generated between the first end and the second end of each N-type element 36. Thus, an electromotive force is generated between a pair of terminals 42 and 44 of the thermoelectric generator 32. A load may be electrically connected between the terminals 42 and 44 to output electric power.

The pair of thermoelectric modules 14 and 16 are disposed so as to face each other with a distance therebetween in the up-down direction. Each of the upper thermoelectric module 14 (first thermoelectric module) and the lower thermoelectric module 16 (second thermoelectric module) generates an electromotive force based on the temperature difference between the high-temperature fluid that flows through the high-temperature fluid passage 12 and the low-temperature fluid that flows through the low-temperature fluid passage 10.

In the present embodiment, two sets, each of the sets including the low-temperature fluid passages 10 and the pair of thermoelectric modules 14 and 16, are provided. The two sets, each of the sets including the low-temperature fluid passages 10 and the pair of thermoelectric modules 14 and 16, are disposed so as to face each other with a distance therebetween in the up-down direction (the Z-axis direction).

The two sets, each of the sets including the low-temperature fluid passages 10 and the pair of thermoelectric modules 14 and 16, may be stacked in the up-down direction. That is, two or more sets may be disposed in the predetermined direction, each of the sets including the low-temperature fluid passages 10, a pair of magnetic body portions 48 and 50, and the pair of thermoelectric modules 14 and 16. With such a stack structure, it is possible to make the thermoelectric conversion unit 2 compact. With such a stack structure, it is possible to further increase the power generation efficiency of the thermoelectric conversion unit 2. Alternatively, three or more sets, each of the sets including the low-temperature fluid passages 10 and the pair of thermoelectric modules 14 and 16, may be stacked in the up-down direction.

### 1-2. Structure for Fixing Thermoelectric Conversion Unit

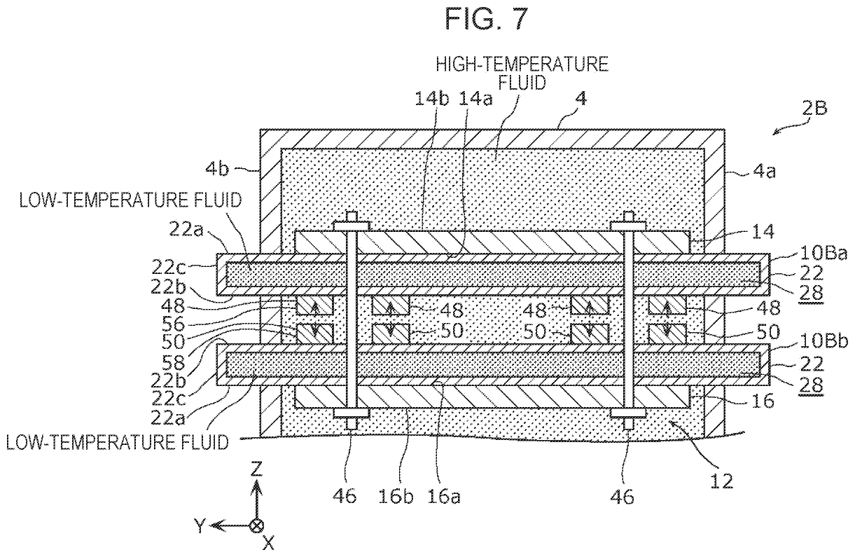

Referring to FIGS. 3 and 5, a structure for fixing the thermoelectric conversion unit 2 according to the first embodiment will be described. FIG. 5 is a plan view of the thermoelectric generator 32 according to the first embodiment.

As illustrated in FIG. 3, guide members 46 and pairs of magnetic body portions 48 and 50 are used as the structure for fixing the thermoelectric conversion unit 2.

Each guide member 46 has an elongated round-bar-like shape. The guide member 46 extends in the predetermined direction through the upper thermoelectric module 14, the housing 22 of the low-temperature fluid passage 10, and the lower thermoelectric module 16. Both end portions of the guide member 46 in the longitudinal direction are fixed to the high-temperature fluid passage 12. With the guide member 46, it is possible to restrain the low-temperature fluid passage 10 from becoming displaced (shifted sideways) with respect to the pair of thermoelectric modules 14 and 16 in a direction perpendicular to (an example of crossing) the predetermined direction. Both end portions of the guide member 46 in the longitudinal direction may be a first end portion and a second end portion.

As illustrated in FIG. 5, through-holes 52 and 54 for inserting the guide members 46 are formed in the thermoelectric generators 32 of the pair of thermoelectric modules 14 and 16. The through-holes 52 (54) extend through the inside of the thermoelectric generator 32 of the upper thermoelectric module 14 (the lower thermoelectric module 16) so as to avoid the P-type elements 34 and the N-type elements 36 (see FIG. 4). In the example illustrated in FIG. 5, four through-hole 52 (54) are formed in one thermoelectric generator 32. However, this is not a limitation. Any appropriate number of through-holes 52 (54) may be formed in one thermoelectric generator 32.

The pair of magnetic body portions 48 and 50 are disposed inside of the housing 22 of the low-temperature fluid passage 10. The pair of magnetic body portions 48 and 50 respectively include block-shaped magnetic bodies 56 and 58. Each of the magnetic bodies 56 and 58 is, for example, a permanent magnet such as a samarium-cobalt magnet, a neodymium magnet, an alnico magnet, a ferrite magnet, or the like. Each surface of the magnetic bodies 56 and 58 may be covered with, for example, a plating film, a resin, or the like.

The magnetic body 56 of the magnetic body portion 48 is disposed on the back surface side of the first main surface 22a of the housing 22. The magnetic body 58 of the magnetic body portion 50 is disposed on the back surface side of the second main surface 22b of the housing 22. The magnetic body 56 of the magnetic body portion 48 and the magnetic body 58 of the magnetic body portion 50 are disposed so that magnetic poles thereof that are the same each other face each other. For example, the magnetic body 56 of the magnetic body portion 48 and the magnetic body 58 of the magnetic body portion 50 are disposed so that the N-pole of the magnetic body 56 and the N-pole of the magnetic body 58 face each other.

Thus, the magnetic body 56 of the magnetic body portion 48 and the magnetic body 58 of the magnetic body portion 50 generate magnetic forces that repel each other (repulsive forces) inside of the housing 22 of the low-temperature fluid passage 10. Therefore, the magnetic body 56 of the magnetic body portion 48 presses the first main surface 22a of the housing 22 toward the upper thermoelectric module 14, and the magnetic body 58 of the magnetic body portion 50 presses the second main surface 22b of the housing 22 toward the lower thermoelectric module 16. That is, the first main surface 22a and the second main surface 22b of the housing 22 respectively deform so as to be pressed against the upper thermoelectric module 14 and the lower thermoelectric module 16. As a result, the thermal contact between the low-temperature fluid passage 10 and the upper thermoelectric module 14 and the thermal contact between the low-temperature fluid passage 10 and the lower thermoelectric module 16 are promoted. At this time, the outer peripheral surface 22c of the housing 22 can absorb a stress that is generated due to the deformation of the low-temperature fluid passage 10 when the magnetic body 56 of the magnetic body portion 48 and the magnetic body 58 of the magnetic body portion 50 repel each other.

Here, when PoS is defined as a pressure that the third main surface 14a of the upper thermoelectric module 14 receives from the low-temperature fluid passage 10, PoS satisfies the following expression (1):

10 kPa≤PoS≤1 MPa (1).

Likewise, when PoS is defined as a pressure that the third main surface 16a of the lower thermoelectric module 16 receives from the low-temperature fluid passage 10, PoS satisfies the above expression (1).

If PoS is lower than 10 kPa, the thermal contact between the low-temperature fluid passage 10 and the upper thermoelectric module 14 and the thermal contact between the low-temperature fluid passage 10 and the lower thermoelectric module 16 are insufficient. On the other hand, if PoS is higher than 1 MPa, the pair of thermoelectric modules 14 and 16 may become damaged.

### 1-3. Method of Using Thermoelectric Conversion Unit

Next, referring to FIGS. 1 and 2, a method of using the thermoelectric conversion unit 2 according to the first embodiment will be described.

As illustrated in FIGS. 1 and 2, the low-temperature fluid flows into the low-temperature fluid channel 28 of the housing 22 of the low-temperature fluid passage 10 through the low-temperature fluid inlet 24, flows through the low-temperature fluid channel 28, and then is discharged to the outside through the low-temperature fluid outlet 26. The heat of the low-temperature fluid that flows through the low-temperature fluid passage 10 is transferred to the third main surface 14a of the upper thermoelectric module 14, and thus the third main surface 14a of the upper thermoelectric module 14 is cooled. The heat of the low-temperature fluid that flows through the low-temperature fluid passage 10 is transferred to the third main surface 16a of the lower thermoelectric module 16, and thus the third main surface 16a of the lower thermoelectric module 16 is cooled.

As illustrated in FIGS. 1 and 2, the high-temperature fluid flows into the high-temperature fluid passage 12 through the high-temperature fluid inlet 6, flows through the high-temperature fluid passage 12 in the front-back direction, and then is discharged to the outside through the high-temperature fluid outlet 8. The heat of the high-temperature fluid that flows through the high-temperature fluid passage 12 is transferred to the fourth main surface 14b of the upper thermoelectric module 14 and the fourth main surface 16b of the lower thermoelectric module 16 through the heat-transfer fins 30. Thus, the fourth main surface 14b of the upper thermoelectric module 14 and the fourth main surface 16b of the lower thermoelectric module 16 are heated.

In the way described above, a temperature difference (temperature gradient) is generated in the thickness direction of the upper thermoelectric module 14 (the Z-axis direction) in such a way that the upper surface side has a higher temperature and the lower surface side has a lower temperature. Thus, an electromotive force is generated between a pair of terminals (not shown) of the upper thermoelectric module 14 due to the temperature difference between the upper surface side and the lower surface side (that is, the temperature difference between the high-temperature fluid and the low-temperature fluid). A load may be electrically connected between the pair of terminals to output electric power.

A temperature difference (temperature gradient) is generated in the thickness direction of the lower thermoelectric module 16 (the Z-axis direction) in such a way that the upper surface side has a lower temperature and the lower surface side has a higher temperature. Thus, an electromotive force is generated between a pair of terminals (not shown) of the lower thermoelectric module 16 due to the temperature difference between the upper surface side and the lower surface side (that is, the temperature difference between the high-temperature fluid and the low-temperature fluid). A load may be electrically connected between the pair of terminals to output electric power.

### 1-4. Advantageous Effects

In the present embodiment, as described above, the pair of magnetic body portions 48 and 50 are disposed in the low-temperature fluid passage 10 Thus, it is possible to cool the magnetic bodies 56 and 58 by using the low-temperature fluid that flows through the low-temperature fluid passage 10, and it is possible to suppress increase in the temperature of the magnetic bodies 56 and 58. Thus, it is possible to suppress decrease of the magnetic moment of the magnetic bodies 56 and 58, the thermal contact between the low-temperature fluid passage 10 and the upper thermoelectric module 14 and the thermal contact between the low-temperature fluid passage 10 and the lower thermoelectric module 16 are promoted, and it is possible to increase the power generation efficiency of the pair of thermoelectric modules 14 and 16.

The low-temperature fluid passage 10, the high-temperature fluid passage 12, and the pair of thermoelectric modules 14 and 16 are fixed to each other by using the magnetic forces with which the magnetic body 56 of the magnetic body portion 48 and the magnetic body 58 of the magnetic body portion 50 repel each other. Thus, the relative positional relationship among the low-temperature fluid passage 10, the high-temperature fluid passage 12, and the pair of thermoelectric modules 14 and 16 has a degree of freedom. As a result, for example, even when a vibration, a thermal impact, or the like is applied to the thermoelectric conversion unit 2 from the outside, it is possible to suppress damage to the pair of thermoelectric modules 14 and 16 by absorbing a stress applied to the pair of thermoelectric modules 14 and 16, because the low-temperature fluid passage 10, the high-temperature fluid passage 12, and the pair of thermoelectric modules 14 and 16 become displaced relative to each other.

### 1-5. Modifications

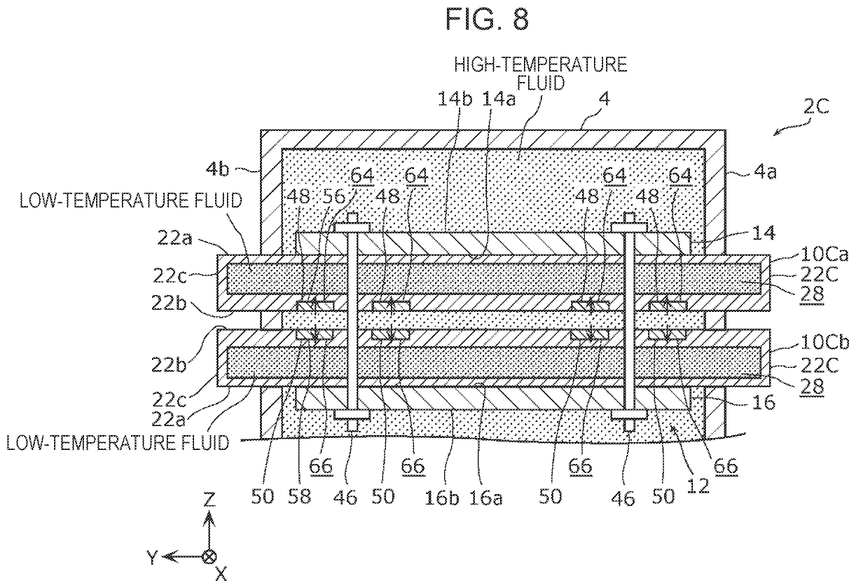

Referring to FIG. 6, the configuration of a thermoelectric conversion unit 2A according to a modification of the first embodiment will be described. FIG. 6 is a partial sectional view of the thermoelectric conversion unit 2A according to the modification of the first embodiment.

As illustrated in FIG. 6, in the thermoelectric conversion unit 2A according to the modification of the first embodiment, grooves 60 that protrude toward the upper thermoelectric module 14 are formed on the back surface side of the first main surface 22a of a housing 22A of a low-temperature fluid passage 10A. Grooves 62 that protrude toward the lower thermoelectric module 16 are formed on the back surface side of the second main surface 22b the housing 22A of a low-temperature fluid passage 10A. The magnetic body 56 of the magnetic body portion 48 is disposed inside of each of the grooves 60. The magnetic body 58 of the magnetic body portion 50 is disposed inside of each of the grooves 62. It may be interpreted that four pairs of grooves are illustrated in FIG. 6. Each pair of grooves include the groove 60 and the groove 62 corresponding to the groove 60.

In the same way as described above, the magnetic body 56 of the magnetic body portion 48 and the magnetic body 58 of the magnetic body portion 50 are disposed so that magnetic poles thereof that are the same each other face each other. Thus, the magnetic body 56 of the magnetic body portion 48 and the magnetic body 58 of the magnetic body portion 50 generate magnetic forces that repel each other inside of the housing 22A of the low-temperature fluid passage 10A. Accordingly, also with the present modification, it is possible to obtain advantageous effects that are the same as those described above.

### Second Embodiment

### 2-1. Configuration of Thermoelectric Conversion Unit

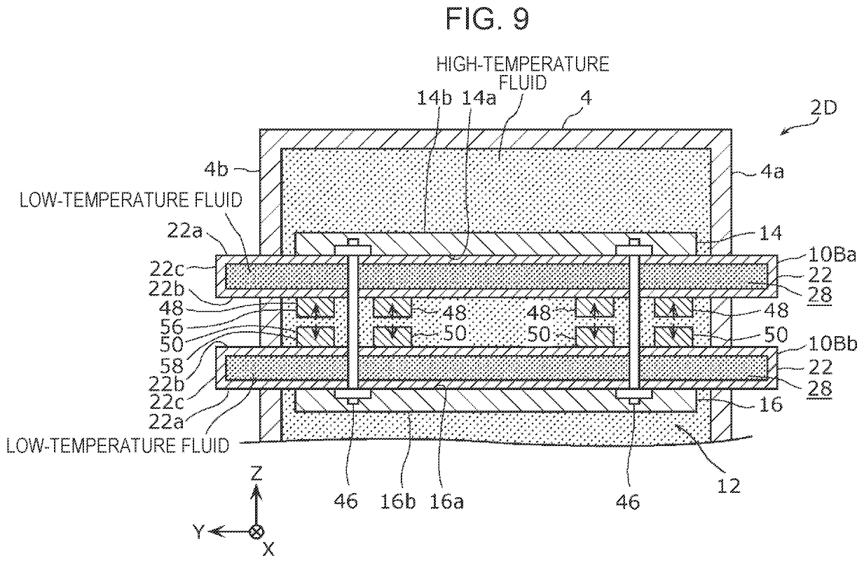

Referring to FIG. 7, a thermoelectric conversion unit 2B according to a second embodiment will be described. FIG. 7 is a partial sectional view of the thermoelectric conversion unit 2B according to the second embodiment. In each of the embodiments described below, elements that are the same as those of the first embodiment will be denoted by the same numerals and descriptions thereof will be omitted.

In the first embodiment, a single low-temperature fluid passage 10 is disposed between the pair of thermoelectric modules 14 and 16. In contrast, as illustrated in FIG. 7, in the thermoelectric conversion unit 2B according to the second embodiment, a pair of low-temperature fluid passages 10Ba and 10Bb are disposed between the pair of thermoelectric modules 14 and 16. The pair of low-temperature fluid passages 10Ba and 10Bb are disposed so as to face each other with a distance therebetween in the predetermined direction.

The first main surface 22a of the housing 22 of the low-temperature fluid passage 10Ba faces in the positive direction of the Z axis, and is in contact with the third main surface 14a of the upper thermoelectric module 14. The second main surface 22b of the housing 22 of the low-temperature fluid passage 10Ba faces in the negative direction of the Z axis, and is in contact with the high-temperature fluid passage 12 (faces the lower thermoelectric module 16).

The first main surface 22a of the housing 22 of the low-temperature fluid passage 10Bb faces in the negative direction of the Z axis, and is in contact with the third main surface 16a of the lower thermoelectric module 16. The second main surface 22b of the housing 22 of the low-temperature fluid passage 10Bb faces in the positive direction of the Z axis, and is in contact with the high-temperature fluid passage 12 (faces the upper thermoelectric module 14).

The pair of magnetic body portions 48 and 50 are disposed between the pair of low-temperature fluid passages 10Ba and 10Bb. That is, the pair of magnetic body portions 48 and 50 are respectively disposed on surfaces of the housings 22 of the pair of low-temperature fluid passages 10Ba and 10Bb. To be more specific, the magnetic body 56 of the magnetic body portion 48 is disposed on the second main surface 22b of the housing 22 of the low-temperature fluid passage 10Ba. The magnetic body 58 of the magnetic body portion 50 is disposed on the second main surface 22b of the housing 22 of the low-temperature fluid passage 10Bb.

The magnetic body 56 of the magnetic body portion 48 and the magnetic body 58 of the magnetic body portion 50 are disposed so that magnetic poles thereof that are the same each other face each other, and therefore generate magnetic forces that repel each other between the pair of low-temperature fluid passages 10Ba and 10Bb. Thus, the magnetic body 56 of the magnetic body portion 48 presses the housing 22 of the low-temperature fluid passage 10Ba toward the upper thermoelectric module 14, and the magnetic body 58 of the magnetic body portion 50 presses the housing 22 of the low-temperature fluid passage 10Bb toward the lower thermoelectric module 16. As a result, the thermal contact between the low-temperature fluid passage 10Ba and the upper thermoelectric module 14 and the thermal contact between the low-temperature fluid passage 10Bb and the lower thermoelectric module 16 are promoted.

### 2-2. First Modification

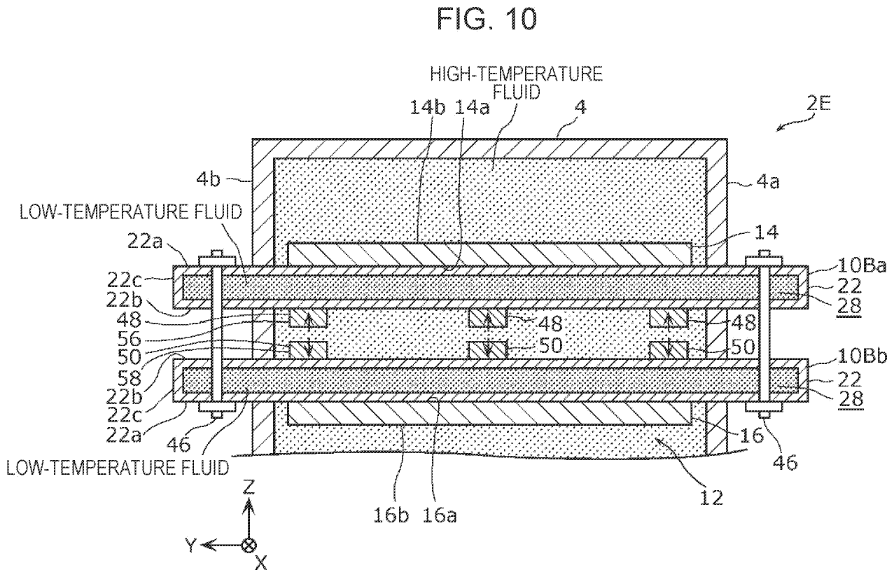

Referring to FIG. 8, a thermoelectric conversion unit 2C according to a first modification of the second embodiment will be described. FIG. 8 is a partial sectional view of the thermoelectric conversion unit 2C according to the first modification of the second embodiment.

As illustrated in FIG. 8, in the thermoelectric conversion unit 2C according to the first modification of the second embodiment, grooves 64 that protrude toward the upper thermoelectric module 14 are formed in the second main surface 22b of a housing 22C of a low-temperature fluid passage 10Ca. Grooves 66 that protrude toward the lower thermoelectric module 16 are formed in the second main surface 22b of a housing 22C of a low-temperature fluid passage 10Cb. The magnetic body 56 of the magnetic body portion 48 is disposed inside of each of the grooves 64. The magnetic body 58 of the magnetic body portion 50 is disposed inside of each of the grooves 66.

In the same way as described above, the magnetic body 56 of the magnetic body portion 48 and the magnetic body 58 of the magnetic body portion 50 are disposed so that magnetic poles thereof that are the same as each other face each other. Thus, the magnetic body 56 of the magnetic body portion 48 and the magnetic body 58 of the magnetic body portion 50 generate magnetic forces that repel each other between the pair of low-temperature fluid passages 10Ca and 10Cb. Accordingly, also with the present modification, it is possible to obtain advantageous effects that are the same as those described above.

### 2-3. Second Modification

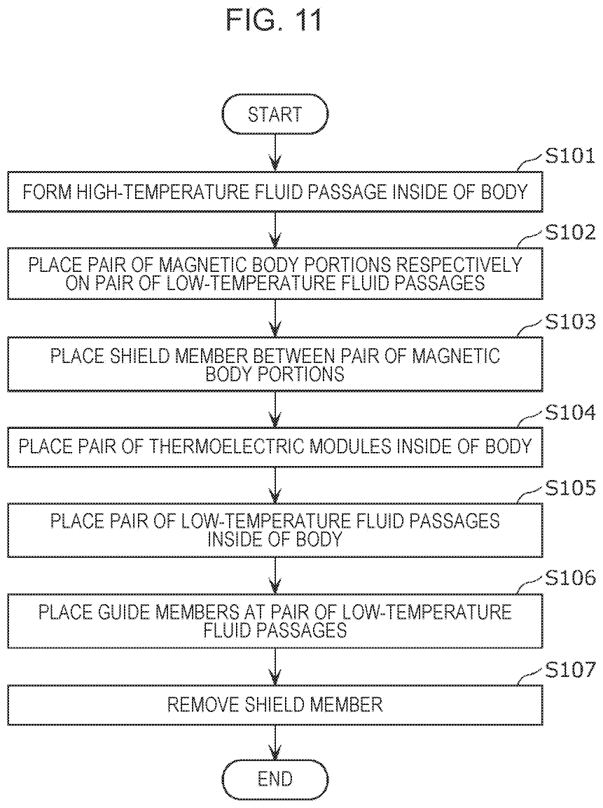

Referring to FIG. 9, a thermoelectric conversion unit 2D according to a second modification of the second embodiment will be described. FIG. 9 is a partial sectional view of the thermoelectric conversion unit 2D according to the second modification of the second embodiment.

As illustrated in FIG. 9, in the thermoelectric conversion unit 2D according to the second modification of the second embodiment, both end portions of the guide members 46 in the longitudinal direction are respectively fixed to the pair of thermoelectric modules 14 and 16. Also with such a configuration, it is possible to obtain advantageous effects that are the same as those described above.

### Third Embodiment

### 3-1. Configuration of Thermoelectric Conversion Unit

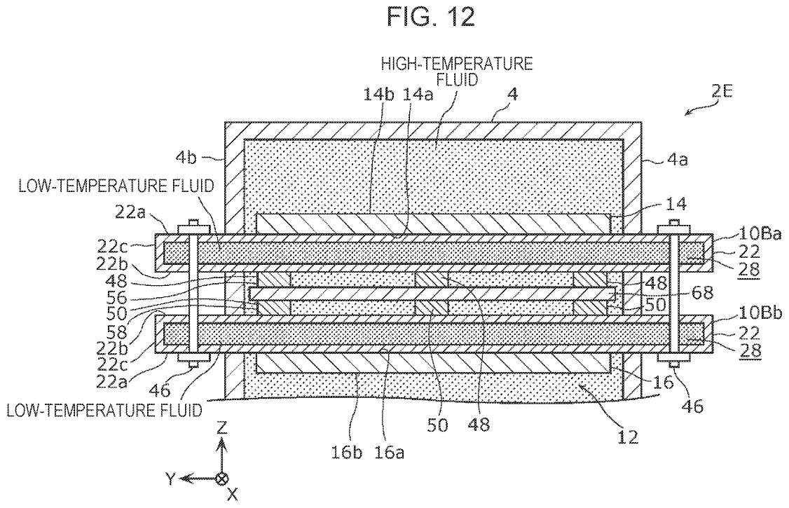

Referring to FIG. 10, a thermoelectric conversion unit 2E according to a third embodiment will be described. FIG. 10 is a partial sectional view of the thermoelectric conversion unit 2E according to the third embodiment.

In the second embodiment, both end portions of the guide members 46 in the longitudinal direction are respectively fixed to the high-temperature fluid passage 12. In contrast, in the thermoelectric conversion unit 2E according to the third embodiment, both end portions of the guide members 46 in the longitudinal direction are respectively fixed, at positions outside of the body 4, to the pair of low-temperature fluid passages 10Ba and 10Bb.

To be more specific, both end portions of one of the guide members 46 in the longitudinal direction are respectively fixed to first end portions in the left-right direction (the Y-axis direction) of the pair of low-temperature fluid passages 10Ba and 10Bb, that is, to first end portions extending through the pair of side surfaces 4a of the body 4 and protruding to the outside of the body 4. Both end portions of the other guide member 46 in the longitudinal direction are respectively fixed to second end portions in the left-right direction of the pair of low-temperature fluid passages 10Ba and 10Bb, that is, to the second end portions extending through the pair of side surfaces 4b of the body 4 and protruding to the outside of the body 4.

### 3-2. Method of Manufacturing Thermoelectric Conversion Unit

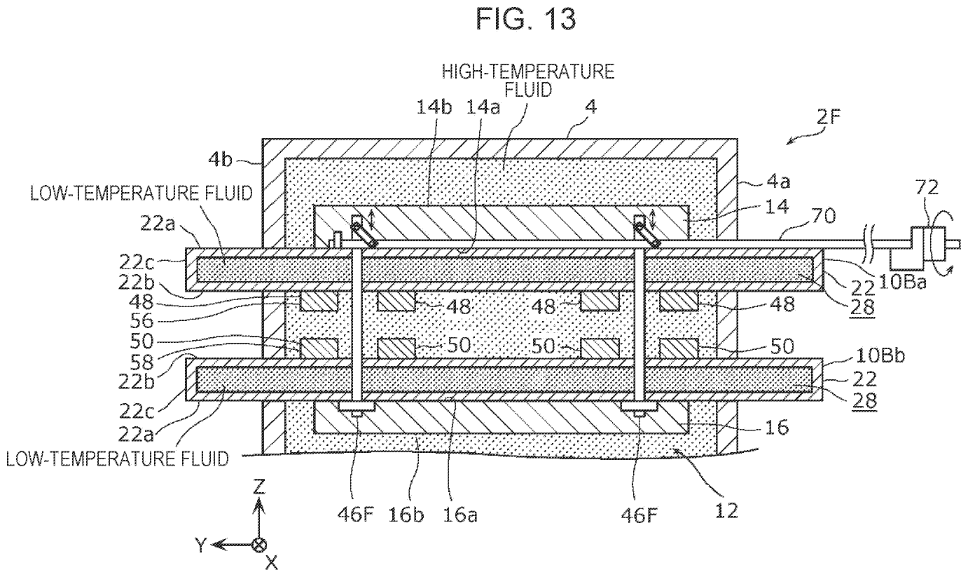

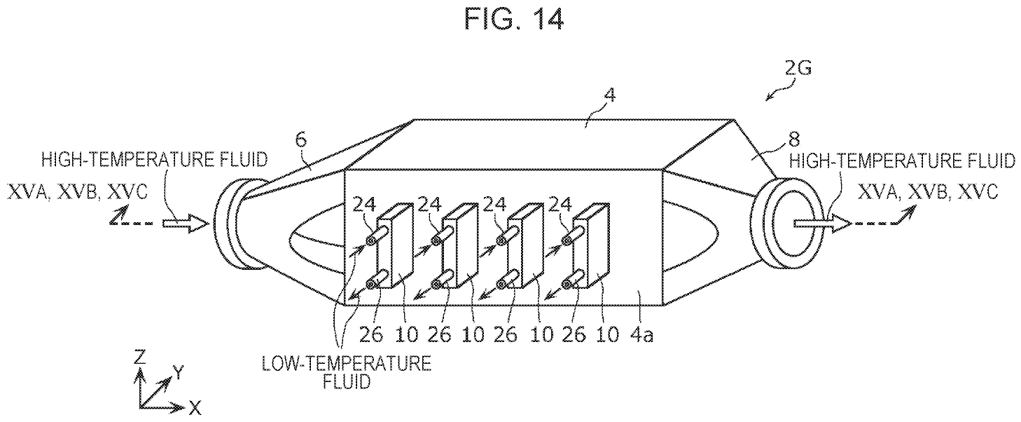

Referring to FIGS. 11 and 12, a method of manufacturing the thermoelectric conversion unit 2E according to the third embodiment will be described. FIG. 11 is a flowchart of the method of manufacturing the thermoelectric conversion unit 2E according to the third embodiment. FIG. 12 is a view for illustrating the method of manufacturing the thermoelectric conversion unit 2E according to the third embodiment.

As illustrated in FIG. 11, first, the high-temperature fluid passage 12 is formed inside of the body 4 (S101). Next, the pair of magnetic body portions 48 and 50 are respectively placed on the pair of low-temperature fluid passages 10Ba and 10Bb (S102), and a shield member 68 (see FIG. 12) is placed between the pair of magnetic body portions 48 and 50 (S103). The shield member 68, which is a member for blocking a magnetic field generated between the pair of magnetic body portions 48 and 50, is a plate made of, for example, stainless steel, a carbon sheet, or the like. The magnetic body portions 48 may be placed on the pair of low-temperature fluid passages 10Ba and 10Bb, and then the shield member 68 and the magnetic body portions 50 may be placed in this order.

Next, the pair of thermoelectric modules 14 and 16 are placed inside of the body 4 (S104), and the pair of low-temperature fluid passages 10Ba and 10Bb are placed inside of the body 4 as illustrated in FIG. 12 (S105). That is, the pair of magnetic body portions 48 and 50 and the shield member 68 are placed between the pair of thermoelectric modules 14 and 16. At this time, a repulsive force generated between the magnetic body 56 of the magnetic body portion 48 and the magnetic body 58 of the magnetic body portion 50 is weakened by the shield member 68. Therefore, it is possible to easily adjust the relative positional relationship between the pair of thermoelectric modules 14 and 16 and the pair of low-temperature fluid passages 10Ba and 10Bb. S104 may be performed after S105. To be more specific, as illustrated in FIG. 12, the pair of low-temperature fluid passages 10Ba and 10Bb may be placed inside of the body 4 (S105), and then the pair of thermoelectric modules 14 and 16 may be placed inside of the body 4 (S104). For example, as illustrated in FIG. 12, the thermoelectric module 14 is placed, inside of the body 4, on the first main surface 22a of the low-temperature fluid passage 10Ba. Likewise, for example, as illustrated in FIG. 12, the thermoelectric module 16 is placed, inside of the body 4, on the first main surface 22a of the low-temperature fluid passage 10Bb. Next, both end portions of the guide members 46 in the longitudinal direction are respectively placed (fixed), at positions outside of the body 4, on (to) the pair of low-temperature fluid passages 10Ba and 10Bb (S106).

Lastly, the shield member 68 is removed from the space between the pair of magnetic body portions 48 and 50 (S107). Thus, the magnetic body 56 of the magnetic body portion 48 and the magnetic body 58 of the magnetic body portion 50 generate magnetic forces that repel each other. Therefore, the magnetic body 56 of the magnetic body portion 48 presses the housing 22 of the low-temperature fluid passage 10Ba toward the upper thermoelectric module 14, and the magnetic body 58 of the magnetic body portion 50 presses the housing 22 of the low-temperature fluid passage 10Bb toward the lower thermoelectric module 16. As a result, the relative positional relationship between the pair of thermoelectric modules 14 and 16 and the pair of low-temperature fluid passages 10Ba and 10Bb is fixed.

### 3-3. Advantageous Effects

In the present embodiment, as described above, both end portions of the guide members 46 in the longitudinal direction are respectively fixed, at positions outside of the body 4, to the pair of low-temperature fluid passages 10Ba and 10Bb. Thus, it is possible to easily perform an operation of fixing both end portions of the guide members 46 respectively to the pair of low-temperature fluid passages 10Ba and 10Bb.

By placing the shield member 68 between the pair of magnetic body portions 48 and 50 when the thermoelectric conversion unit 2E is being assembled, a repulsive force generated between the magnetic body 56 of the magnetic body portion 48 and the magnetic body 58 of the magnetic body portion 50 is weakened Thus, it is possible to easily adjust the relative positional relationship between the pair of thermoelectric modules 14 and 16 and the pair of low-temperature fluid passages 10Ba and 10Bb.

### 3-4. Modification

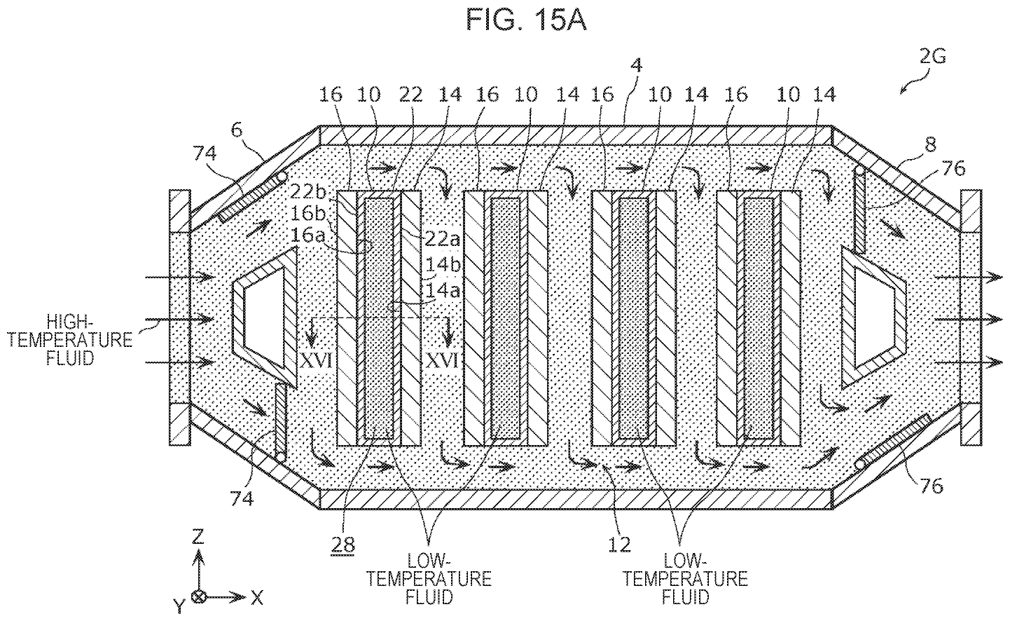

Referring to FIG. 13, the configuration of a thermoelectric conversion unit 2F according to a modification of the third embodiment will be described. FIG. 13 is a partial sectional view of the thermoelectric conversion unit 2F according to the modification of the third embodiment.

As illustrated in FIG. 13, in the thermoelectric conversion unit 2F according to the modification of the third embodiment, both end portions of each of guide members 46F in the longitudinal direction are respectively disposed, inside of the body 4, in the pair of thermoelectric modules 14 and 16. First end portions of the guide members 46F in the longitudinal direction are coupled to a driving source 72 (an example of an adjuster) via a link mechanism 70 (an example of an adjuster). The driving source 72 is, for example, a motor, a rotation handle, or the like.

Rotational motion of the driving source 72 is converted to linear motion of the guide members 46F by the link mechanism 70. Thus, when the driving source 72 and the link mechanism 70 are controlled, the guide members 46F are switched between a first state in which the guide members 46F are fixed to the pair of thermoelectric modules 14 and 16 and a second state in which the guide members 46F are released from being fixed to the pair of thermoelectric modules 14 and 16.

When the guide members 46F are switched to the first state, the pair of low-temperature fluid passages 10Ba and 10Bb are fixed at positions close to each other against the repulsive force of the pair of magnetic body portions 48 and 50. That is, the pair of low-temperature fluid passages 10Ba and 10Bb are constrained by the guide members 46F.

On the other hand, when the guide members 46F are switched to the second state, the pair of low-temperature fluid passages 10Ba and 10Bb become displaced in directions away from each other by the pair of magnetic body portions 48 and 50. That is, the pair of low-temperature fluid passages 10Ba and 10Bb are released from the constraint by the guide members 46F.

For example, by switching the guide members 46F to the first state in step S105 of the flowchart of FIG. 11 when the thermoelectric conversion unit 2F is being manufactured, the pair of low-temperature fluid passages 10Ba and 10Bb are constrained by the guide members 46F. Thus, it is possible to easily adjust the relative positional relationship between the pair of thermoelectric modules 14 and 16 and the pair of low-temperature fluid passages 10Ba and 10Bb.

Subsequently, when the guide members 46F are switched to the second state, the pair of low-temperature fluid passages 10Ba and 10Bb are released from the constraint by the guide members 46F. Thus, the magnetic body 56 of the magnetic body portion 48 presses the housing 22 of the low-temperature fluid passage 10Ba toward the upper thermoelectric module 14, and the magnetic body 58 of the magnetic body portion 50 presses the housing 22 of the low-temperature fluid passage 10Bb toward the lower thermoelectric module 16.

In this way, by appropriately switching the guide members 46F between the first state and the second state when the thermoelectric conversion unit 2F is being manufactured, it is possible to control the repulsive force generated between the magnetic body 56 of the magnetic body portion 48 and the magnetic body 58 of the magnetic body portion 50.

In the present modification, both end portions of the guide members 46F in the longitudinal direction are respectively disposed in the pair of thermoelectric modules 14 and 16. However, this is not a limitation. As in the first embodiment, both end portions of the guide members 46F in the longitudinal direction may be disposed in the high-temperature fluid passage 12.

In the present modification, a case where the guide members 46F are switched between the first state and the second state when the thermoelectric conversion unit 2F is being manufactured has been described. However, this is not a limitation. For example, the guide members 46F may be switched between the first state and the second state when the amount of electric power generated the pair of thermoelectric modules 14 and 16 is to be adjusted. In this case, the amount of generated electric power is the minimum when the guide members 46F are switched to the first state, and the amount of generated electric power is the maximum when the guide members 46F are switched to the second state.

### Fourth Embodiment

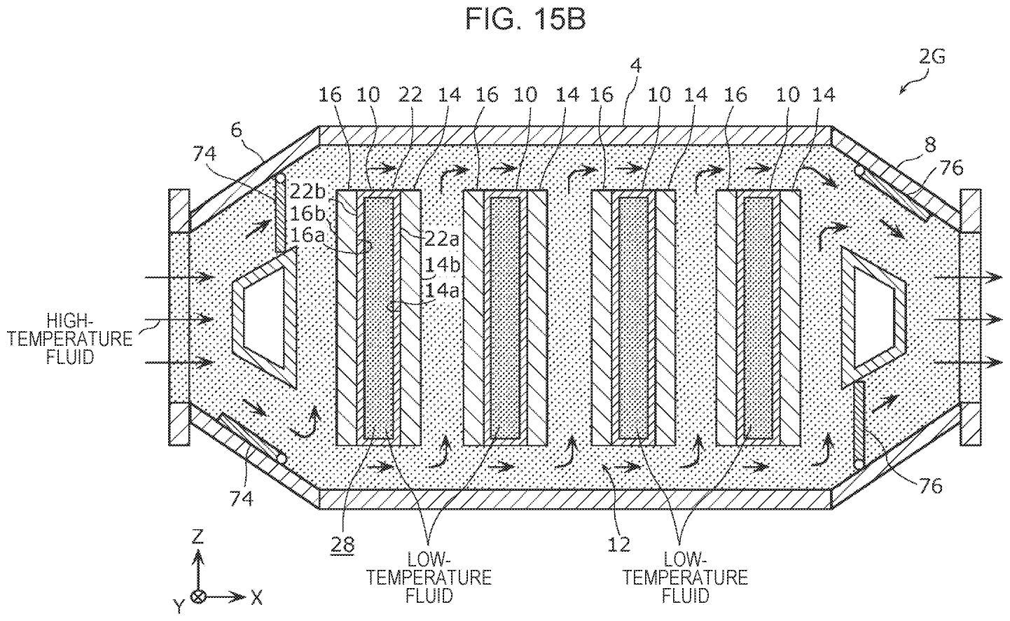

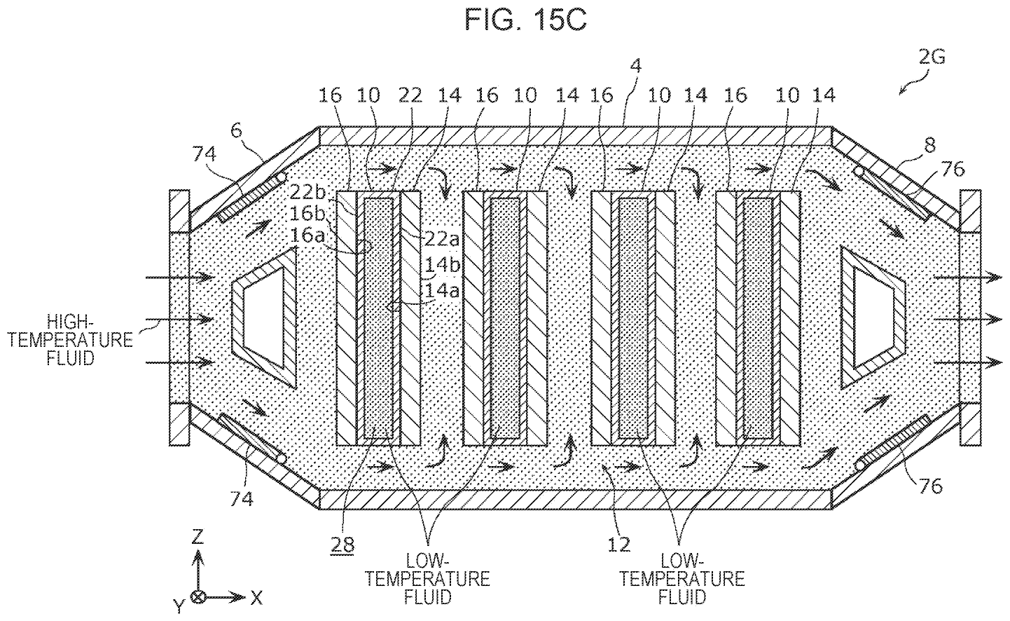

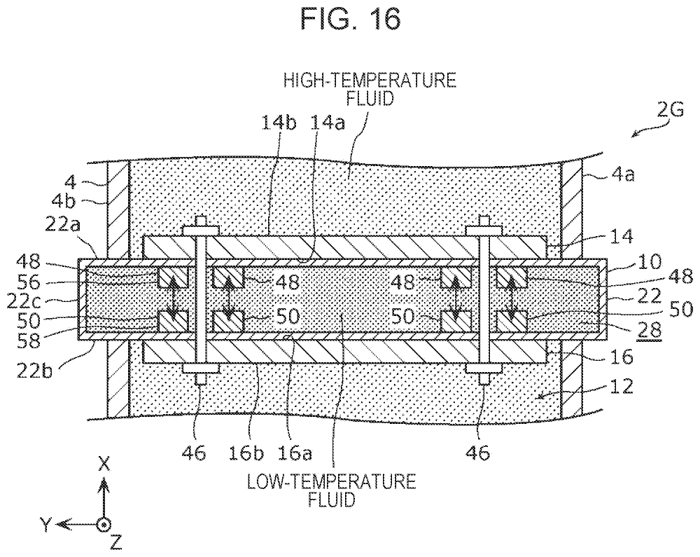

Referring to FIGS. 14 to 16, the configuration of a thermoelectric conversion unit 2G according to a fourth embodiment will be described. FIG. 14 is a perspective view of the thermoelectric conversion unit 2G according to the fourth embodiment. FIG. 15A is a sectional view of the thermoelectric conversion unit 2G according to the fourth embodiment in a first switched state taken along line XVA-XVA of FIG. 14. FIG. 15B is a sectional view of the thermoelectric conversion unit 2G according to the fourth embodiment in a second switched state taken along line XVB-XVB of FIG. 14. FIG. 15C is a sectional view of the thermoelectric conversion unit 2G according to the fourth embodiment in a third switched state taken along line XVC-XVC of FIG. 14. FIG. 16 is a partial sectional view of the thermoelectric conversion unit 2G according to the fourth embodiment taken along line XVI-XVI of FIG. 15A.

As illustrated in FIGS. 14 and 15A, in the thermoelectric conversion unit 2G according to the fourth embodiment, four sets, each of the sets including the low-temperature fluid passage 10 and the pair of thermoelectric modules 14 and 16, are provided. The four sets, each of the sets including the low-temperature fluid passage 10 and the pair of thermoelectric modules 14 and 16, are disposed with distances therebetween in the front-back direction (the X-axis direction). The first main surface 22a the housing 22 of each low-temperature fluid passage 10 faces in the positive direction of the X axis, and the second main surface 22b faces in the negative direction of the X axis. For convenience of description, in FIGS. 15A, 15B, 15C, and 16, illustration of plate-shaped or pin-shaped heat-transfer fins, which are disposed in the high-temperature fluid passage 12, is omitted.

As illustrated in FIG. 15A, inside of the high-temperature fluid inlet 6, a pair of upper and lower passage switchers 74 for switching the flow of the high-temperature fluid in the high-temperature fluid inlet 6 and the high-temperature fluid passage 12 are disposed with a distance therebetween in the up-down direction. The upper passage switcher 74 and the lower passage switcher 74 are respectively configured to be capable of opening and closing an upper passage and a lower passage inside of the high-temperature fluid inlet 6.

Inside of the high-temperature fluid outlet 8, a pair of upper and lower passage switchers 76 for switching the flow of the high-temperature fluid in the high-temperature fluid outlet 8 and the high-temperature fluid passage 12 are disposed with a distance therebetween in the up-down direction. The upper passage switcher 76 and the lower passage switcher 76 are respectively configured to be capable of opening and closing an upper passage and a lower passage inside of the high-temperature fluid outlet 8.

The high-temperature fluid passage 12 is switched by the pair of passage switchers 74 and the pair of passage switchers 76 between a first switched state illustrated in FIG. 15A, a second switched state illustrated in FIG. 15B, and a third switched state illustrated in FIG. 15C.

In the first switched state illustrated in FIG. 15A, the upper passage switcher 74 opens the upper passage inside of the high-temperature fluid inlet 6, and the lower passage switcher 74 closes the lower passage inside of the high-temperature fluid inlet 6. The upper passage switcher 76 closes the upper passage inside of the high-temperature fluid outlet 8, and the lower passage switcher 76 opens the lower passage inside of the high-temperature fluid outlet 8. Thus, the high-temperature fluid flows downward (in the negative direction of the Z axis) between adjacent two sets, each of the sets including the low-temperature fluid passage 10 and the pair of thermoelectric modules 14 and 16.

In the second switched state illustrated in FIG. 15B, the upper passage switcher 74 closes the upper passage inside of the high-temperature fluid inlet 6, and the lower passage switcher 74 opens the lower passage inside of the high-temperature fluid inlet 6. The upper passage switcher 76 opens the upper passage inside of the high-temperature fluid outlet 8, and the lower passage switcher 76 closes the lower passage inside of the high-temperature fluid outlet 8. Thus, the high-temperature fluid flows upward (in the positive direction of the Z axis) between adjacent two sets, each of the sets including the low-temperature fluid passage 10 and the pair of thermoelectric modules 14 and 16.

In the third switched state illustrated in FIG. 15C, the upper passage switcher 74 opens the upper passage inside of the high-temperature fluid inlet 6, and the lower passage switcher 74 opens the lower passage inside of the high-temperature fluid inlet 6. The upper passage switcher 76 opens the upper passage inside of the high-temperature fluid outlet 8, and the lower passage switcher 76 opens the lower passage inside of the high-temperature fluid outlet 8. Thus, the high-temperature fluid that flows downward and the high-temperature fluid that flows upward join at a position between adjacent two sets, each of the sets including the low-temperature fluid passage 10 and the pair of thermoelectric modules 14 and 16.

By switching from one of the first switched state or the second switched state to the other, it is possible to prolong life of the pair of thermoelectric modules 14 and 16 by uniformizing accumulated thermal load in each portion of the thermoelectric modules 14 and 16. By switching to the third switched state, it is possible to reduce the amount of heat to be exchanged and the amount of electric power to be generated by the pair of thermoelectric modules 14 and 16.

As illustrated in FIG. 16, a structure for fixing the thermoelectric conversion unit 2G according to the fourth embodiment G is the same as that of the first embodiment, and description thereof will be omitted.

Accordingly, also with the present embodiment, it is possible to obtain advantageous effects similar to those of the first embodiment.

### Others 1

Heretofore, thermoelectric conversion units according to one or more aspects of the present disclosure have been described based on embodiments. However, the present disclosure is not limited to these embodiments. Within the gist of the present disclosure, the scope of the present disclosure encompasses various modifications of the embodiments that are conceivable by persons having ordinary skill in the art and configurations structured by combinations of elements in different embodiments.

### Others 2

In the embodiments described above, the high-temperature fluid is exhaust gas and the low-temperature fluid is cold water or cold air. However, this is not a limitation. The high-temperature fluid and the low-temperature fluid each may be any liquid or any gas.

### Others 3

A thermoelectric conversion unit according to an aspect of the present disclosure may be as follows.

A thermoelectric conversion unit comprising:
a first fluid passage that has a first main surface and a second main surface opposite to the first main surface,
   a first fluid flowing through the first fluid passage;
a second fluid passage that has a surface a and a surface b opposite to the surface a,
   a second fluid flowing through the second fluid passage,
   the second fluid not flowing through the first fluid passage,
   the first fluid not flowing through the second fluid passage,
   a second temperature of the second fluid being higher than a first temperature of the first fluid, and
   a distance between the first main surface and the surface a being less than a distance between the second main surface and the surface a, and a distance between the first main surface and the surface b being greater than a distance between the second main surface and the surface b;
a first thermoelectric module that is disposed between the surface a and the first main surface,
   the first thermoelectric module generating an electromotive force based on a first difference between the first temperature and the second temperature;
a second thermoelectric module that is disposed between the surface b and the second main surface,
   the second thermoelectric module generating an electromotive force based on the first difference; and
a first magnetic body and a second magnetic body,
   a first portion of the first magnetic body and a second portion of the second magnetic body facing each other along a predetermined direction from the first main surface toward the second main surface and being provided inside of or on a surface of the first fluid passage, and
   a magnetic pole of the first portion being the same as a magnetic pole of the second portion.

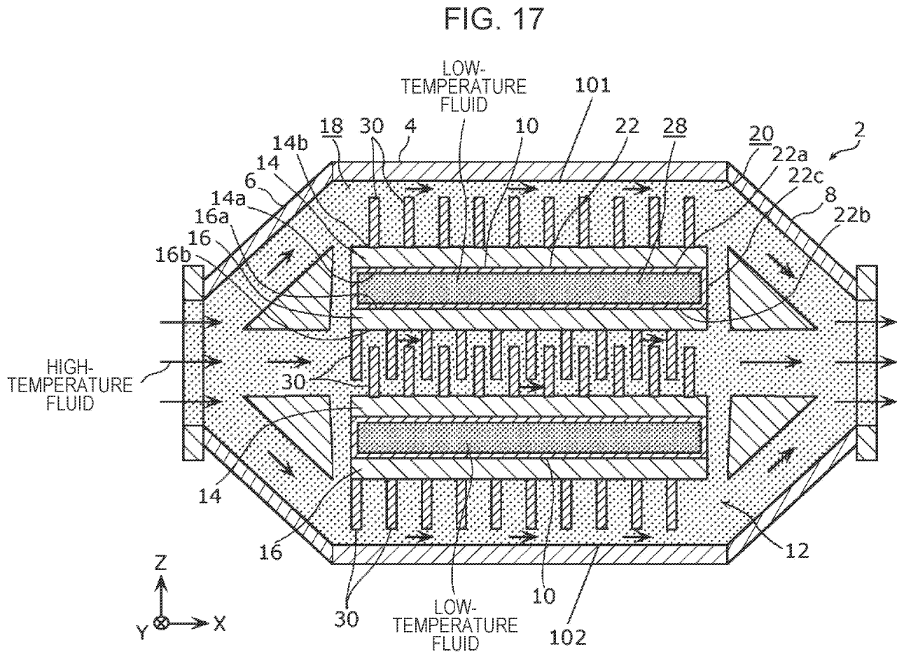

FIG. 17 is a sectional view of the thermoelectric conversion unit according to the first embodiment taken along line XVII-XVII of FIG. 1. As illustrated in FIG. 17, the high-temperature fluid passage 12 (an example of a second fluid passage) has a surface 101 (an example of a surface a) and a surface 102 (an example of a surface b).

A thermoelectric conversion unit according to the present disclosure is used as, for example: a generator that generates electric power by using thermal energy of exhaust gas discharged from an automobile, a factory, or the like; a compact portable generator; or the like.

What is claimed is:

1. A thermoelectric conversion unit comprising:
a first fluid passage that has a first main surface and a second main surface opposite to the first main surface and through which a first fluid flows between the first main surface and the second main surface;
a second fluid passage that is disposed so as to face the first main surface and the second main surface and through which a second fluid having a temperature higher than a temperature of the first fluid flows;
a pair of thermoelectric modules that include a first thermoelectric module disposed between the second fluid passage and the first main surface and a second thermoelectric module disposed between the second fluid passage and the second main surface; and
a pair of magnetic body portions that are disposed inside of or on a surface of the first fluid passage along a predetermined direction from the first main surface toward the second main surface,
wherein each of the first thermoelectric module and the second thermoelectric module generates an electromotive force based on a temperature difference between the temperature of the first fluid and the temperature of the second fluid,
wherein each of the pair of magnetic body portions includes a magnetic body, and
wherein the magnetic bodies of the pair of magnetic body portions are disposed so that magnetic poles thereof that are the same as each other face each other, and the magnetic bodies generate magnetic forces that repel each other.

2. The thermoelectric conversion unit according to claim 1,
wherein two or more sets are disposed in the predetermined direction, each of the sets including the first fluid passage, the pair of magnetic body portions, and the pair of thermoelectric modules.

3. The thermoelectric conversion unit according to claim 1, further comprising:
a guide member,
wherein the guide member extends through an inside of the first fluid passage in the predetermined direction and restrains the first fluid passage from becoming displaced with respect to the pair of thermoelectric modules in a direction crossing the predetermined direction.

4. The thermoelectric conversion unit according to claim 3,
wherein both end portions of the guide member in a longitudinal direction include a first end portion and a second end portion, and
wherein the first end portion and the second end portion are respectively fixed to the pair of thermoelectric modules or the second fluid passage.

5. The thermoelectric conversion unit according to claim 4,
wherein the first end portion, the second end portion, or each of the first end portion and the second end portion includes an adjuster, and
wherein, when the adjuster is controlled, the guide member is switched between a first state in which the guide member is fixed to the pair of thermoelectric modules or the second fluid passage and a second state in which the guide member is released from being fixed to the pair of thermoelectric modules or the second fluid passage.

6. The thermoelectric conversion unit according to claim 1,
wherein the first fluid passage includes a pair of grooves that respectively protrude toward the pair of thermoelectric modules, and
wherein the pair of magnetic body portions are respectively disposed inside of the pair of grooves.

7. The thermoelectric conversion unit according to claim 1,
wherein the first fluid passage includes a pair of first fluid passages,
wherein the pair of first fluid passages are disposed so as to face each other in the predetermined direction, and
wherein the pair of magnetic body portions are disposed between the pair of first fluid passages.

8. The thermoelectric conversion unit according to claim 1,
wherein the second fluid passage includes a pin-shaped heat-transfer fin disposed along the predetermined direction, plate-shaped heat-transfer fins disposed along the predetermined direction so as to face each other, or the pin-shaped heat-transfer fin and the plate-shaped heat-transfer fins.

9. The thermoelectric conversion unit according to claim 1,
wherein each of the pair of thermoelectric modules has
a third main surface that faces the first fluid passage, and
a fourth main surface that faces the second fluid passage, and
wherein, when PoS is defined as a pressure that the third main surface of each of the pair of thermoelectric modules receives from the first fluid passage, the PoS satisfies the following expression (1):
$$10 kPa \leq PoS \leq 1 MPa . \qquad ( 1 )$$

10. The thermoelectric conversion unit according to claim 1,
wherein each of the pair of thermoelectric modules has
a third main surface that faces the first fluid passage, and
a fourth main surface that faces the second fluid passage, and
wherein a heat-transfer member is interposed in a first gap between the first fluid passage and the third main surface, in a second gap between the second fluid passage and the fourth main surface, or between the first gap and the second gap.

11. The thermoelectric conversion unit according to claim 10,
wherein the heat-transfer member is a thermally conductive sheet, thermally conductive grease, or the thermally conductive sheet and the thermally conductive grease.

12. The thermoelectric conversion unit according to claim 1,
wherein the magnetic body is a permanent magnet.

13. The thermoelectric conversion unit according to claim 12,
wherein the permanent magnet is at least one of a samarium-cobalt magnet, a neodymium magnet, an alnico magnet, or a ferrite magnet.

14. The thermoelectric conversion unit according to claim 1,
wherein an outer peripheral surface of the first fluid passage that surrounds a space between the first main surface and the second main surface is made of stainless steel or a resin.

15. The thermoelectric conversion unit according to claim 1,
wherein a passage switcher for switching flow of the second fluid in the second fluid passage is disposed the second fluid passage.

16. A method of manufacturing a thermoelectric conversion unit, comprising:
(a) forming a second fluid passage through which a second fluid having a temperature higher than a temperature of a first fluid flows;
(b) placing a first fluid passage that has a first main surface and a second main surface opposite to the first main surface and through which the first fluid flows so that the second fluid passage faces the first main surface and the second main surface;
(c) placing a pair of thermoelectric modules that include a first thermoelectric module and a second thermoelectric module,
the placing of the pair of thermoelectric modules including
placing the first thermoelectric module between the second fluid passage and the first main surface, and
placing the second thermoelectric module between the second fluid passage and the second main surface; and
(d) placing a pair of magnetic body portions inside of or on a surface of the first fluid passage along a predetermined direction from the first main surface toward the second main surface,
wherein an electromotive force is generated by applying a temperature difference between the temperature of the first fluid and the temperature of the second fluid to each of the pair of thermoelectric modules,
wherein each of the pair of magnetic body portions includes a magnetic body, and
wherein the magnetic bodies of the pair of magnetic body portions are disposed so that magnetic poles thereof that are the same as each other face each other, and the magnetic bodies generate magnetic forces that repel each other.

17. The method of manufacturing a thermoelectric conversion unit according to claim 16,
wherein the (d) further includes
(d1) controlling a repulsive force generated between the magnetic bodies of the pair of magnetic body portions.

18. The method of manufacturing a thermoelectric conversion unit according to claim 17,
wherein the (d) further includes
(d2) placing a guide member that extends through at least an inside of the first fluid passage in the predetermined direction, and
wherein, in the (d1), both end portions of the guide member in a longitudinal direction are respectively fixed to the pair of thermoelectric modules or the second fluid passage.

19. The method of manufacturing a thermoelectric conversion unit according to claim 18,
wherein, in the (d1), the guide member is switched between a first state in which the guide member is fixed to the pair of thermoelectric modules or the second fluid passage and a second state in which the guide member is released from being fixed to the pair of thermoelectric modules or the second fluid passage.

20. The method of manufacturing a thermoelectric conversion unit according to claim 16,
wherein the (d) further comprises:
(d3) placing, between the pair of magnetic body portions, a shield member that blocks a magnetic field generated between the pair of magnetic body portions,
(d4) placing the pair of magnetic body portions and the shield member between the pair of thermoelectric modules, and
(d5) removing the shield member from between the pair of magnetic body portions.

21. A method of using a thermoelectric conversion unit,
the thermoelectric conversion unit including
a first fluid passage that has a first main surface and a second main surface opposite to the first main surface and through which a first fluid flows between the first main surface and the second main surface,
a second fluid passage that is disposed so as to face the first main surface and the second main surface and through which a second fluid having a temperature higher than a temperature of the first fluid flows,
a pair of thermoelectric modules that include a first thermoelectric module disposed between the second fluid passage and the first main surface and a second thermoelectric module disposed between the second fluid passage and the second main surface, and
a pair of magnetic body portions that are disposed inside of or on a surface of the first fluid passage along a predetermined direction from the first main surface toward the second main surface,
wherein each of the pair of magnetic body portions includes a magnetic body, and
wherein the magnetic bodies of the pair of magnetic body portions are disposed so that magnetic poles thereof that are the same as each other face each other, and the magnetic bodies generate magnetic forces that repel each other,
the method comprising:
transferring heat of the second fluid to each of the pair of thermoelectric modules; and
generating an electromotive force by applying a temperature difference between the temperature of the first fluid and the temperature of the second fluid to each of the pair of thermoelectric modules.

22. A thermoelectric conversion unit comprising:
a first fluid passage that has a first main surface and a second main surface opposite to the first main surface,
a first fluid flowing through the first fluid passage;
a second fluid passage that has a surface a and a surface b opposite to the surface a,
a second fluid flowing through the second fluid passage,
the second fluid not flowing through the first fluid passage,
the first fluid not flowing through the second fluid passage,
a second temperature of the second fluid being higher than a first temperature of the first fluid, and
a distance between the first main surface and the surface a being less than a distance between the second main surface and the surface a, and a distance between the first main surface and the surface b being greater than a distance between the second main surface and the surface b;
a first thermoelectric module that is disposed between the surface a and the first main surface,
the first thermoelectric module generating an electromotive force based on a first difference between the first temperature and the second temperature;
a second thermoelectric module that is disposed between the surface b and the second main surface,
the second thermoelectric module generating an electromotive force based on the first difference; and
a first magnetic body and a second magnetic body,
a first portion of the first magnetic body and a second portion of the second magnetic body facing each other along a predetermined direction from the first main surface toward the second main surface and being provided inside of or on a surface of the first fluid passage, and
a magnetic pole of the first portion being the same as a magnetic pole of the second portion.
